(19) United States
(12) Patent Application Publication
(10) Pub. No.: US 2005/0250321 A1
(43) Pub. Date: Nov. 10, 2005

(54) Method for fabricating semiconductor device having diffusion barrier layer

(76) Inventor: Eui-Seong Hwang, Kyoungki-do (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/020,750

(22) Filed: Dec. 21, 2004

(30) Foreign Application Priority Data
May 6, 2004 (KR) 2004-31921

(51) Int. Cl. H01L 21/44

(52) U.S. Cl. 438/672

(57) ABSTRACT

The present invention relates to a method for fabricating a diffusion barrier layer of a semiconductor device. The method includes the steps of: forming an insulation layer a metal interconnection line; etching the insulation layer, thereby forming an opening to expose a portion of the metal interconnection line; forming a soaking layer on the insulation layer and the opening; forming a diffusion barrier layer on the soaking layer; and filling a metal layer into the opening.

### FIELD OF THE INVENTION

The present invention relates to a method for fabricating a semiconductor device; and more particularly, to a method for fabricating a diffusion barrier layer in a semiconductor device.

### DESCRIPTION OF RELATED ARTS

In a semiconductor device, a diffusion barrier layer serves a role in delaying diffusion to the maximum extent or preventing a chemical reaction between an interconnection line and a substrate, and between the interconnection lines. A stable diffusion barrier layer is essentially required to develop a reliable semiconductor device. However, the diffusion barrier layer cannot perfectly prevents the diffusion and thus, a capability of the diffusion barrier layer depends on how long the diffusion barrier layer can be durable under various conditions of a thermal process.

There are required properties for the diffusion barrier layer. The diffusion barrier should be thermodynamically stable even under a condition that the diffusion barrier layer contacts to the interconnection line and the substrate by being formed between the interconnection line and the substrate. Also, the diffusion barrier layer should have excellent adhesion and low contact resistance. Furthermore, the diffusion barrier layer should have strong tolerance to a thermal and mechanical stress, have a similar heat expansion coefficient to the substrate, and have excellent electric conductivity.

Recently, as a scale of integration of a semiconductor device increases, an aspect ratio of an opening connecting an upper interconnection line with a lower interconnection line greatly increases. A chemical vapor deposition method is used as a method for filling such contact hole having a large aspect ratio by using a metal, for instance, a tungsten (W) layer. Hereinafter, a process for forming a tungsten layer through the use of a chemical vapor deposition method is expressed as a CVD tungsten process.

As for the above mentioned CVD tungsten process, the tungsten layer uses tungsten hexafluoride (WF₆) as a precursor. At this time, a method for precedently depositing titanium nitride (TiN) used as the diffusion barrier layer is employed to prevent the precursor and decomposed components of the precursor from penetrating into lower layers. When depositing the TiN, a physical vapor deposition (PVD) method is mainly used; however, recently as the aspect ratio increases, a chemical vapor deposition (CVD) method is more frequently used.

FIGS. 1A and 1B are diagrams briefly illustrating a method for forming a metal contact through a conventional CVD tungsten process.

Referring to FIG. 1A, an inter-metal insulation layer 12 is formed on a lower metal interconnection line 11. Then, the inter-metal insulation layer 12 is etched, thereby forming an opening 13 exposing a portion of the lower interconnection line 11.

Next, a diffusion barrier layer 14 is deposited on the contact hole 13 and on the inter-metal insulation layer 12. Then, a tungsten layer 15 is deposited on the diffusion barrier layer 14 until filling the contact hole 13 through the CVD tungsten process. At this time, the diffusion barrier layer 14 is formed by stacking a titanium (Ti) layer and a titanium nitride (TiN) layer, and when depositing the tungsten layer 15 through the CVD method, a source gas uses tungsten hexafluoride (WF₆).

Referring to FIG. 1B, a chemical mechanical polishing (CMP) process or an etch-back process is performed. From this process, the diffusion layer 14 and the tungsten layer 15 shown in FIG. 1A remain only inside of the contact hole 13 until a surface of the inter-metal insulation layer 12 is exposed. Herein, a reference numeral 15A denotes a tungsten plug which is a remaining tungsten layer. The tungsten plug 15A serves a role of a metal contact that connects the lower metal interconnection line 11 with a subsequent upper metal interconnection line.

Next, another titanium nitride (TiN) layer 16 is deposited on the tungsten plug 15A as an adhesive layer, and a tungsten layer 17 is deposited on the titanium nitride layer 16. Then, the tungsten layer 17 and the titanium nitride layer 16 are patterned, thereby forming the upper metal interconnection line.

In this conventional method, the titanium nitride (TiN) layers are used as the diffusion barrier layer and the titanium (Ti) layer is used as a wetting layer of the TiN layer.

Since the aspect ratio of the contact hole rapidly increases as a scale of integration of the semiconductor device increase, there requires a lot of changes in the diffusion barrier layer. For instance, in case of a memory device with a size equal to or less than 100 nm, a method directly depositing a thin titanium nitride (TiN) layer through a CVD method without depositing a titanium (Ti) layer is proposed to reduce the contact resistance.

However, in case of only depositing the TiN layer, the adhesion of the TiN layer with the inter-metal insulation layer deposited below the TiN layer is worsened. Also, since the TiN layer grows with an island type, it is difficult to form a continuous thin layer. Thus, there is a disadvantage that TiN should be deposited with a thickness more than a predetermined thickness to form the continuous thin layer. In addition, an increase in the contact resistance is not avoidable because a resistivity increases as a thickness of the TiN layer increases. That is, the TiN layer deposited through the CVD method has higher resistivity than the tungsten layer, i.e., a main burying metal, thereby inducing an increase in the contact resistance. Also, the contact resistance increases in greater extents because if a thickness of the TiN layer gets thicker to secure the intended role of the TiN layer, i.e., the role as a diffusion barrier layer, a substance having a high resistivity is deposited thickly.

The increase in the contact resistance as mentioned above may cause a problem that the contact resistance increases in greater extents as the aspect ratio of the contact hole increases.

Accordingly, it is necessary to deposit the diffusion barrier layer as thinly as possible as not degrading the diffusion barrier capability. Furthermore, it is an essential condition to improve the adhesion between the diffusion barrier layer and the lower layer.

### SUMMARY OF THE INVENTION

It is, therefore, an object of the present invention to provide a method for fabricating a semiconductor device having a diffusion barrier layer capable of securing a diffusion barrier capability as having excellent adhesion with lower layers.

In accordance with one aspect of the present invention, there is provided a method for fabricating a semiconductor device, including the steps of: forming an insulation layer a metal interconnection line; etching the insulation layer, thereby forming an opening to expose a portion of the metal interconnection line; forming a soaking layer on the insulation layer and the opening; forming a diffusion barrier layer on the soaking layer; and filling a metal layer into the opening.

In accordance with another aspect of the present invention, there is provided a method for fabricating a semiconductor device, including the steps of: forming an insulation layer on a semiconductor layer containing silicon; etching the insulation layer, thereby forming an opening to expose a portion of the semiconductor layer; forming a silicide layer on the exposed portion of the semiconductor layer; forming a soaking layer on the silicide layer and the opening; forming a diffusion barrier layer on the soaking layer; and filling the opening with a metal layer.

### BRIEF DESCRIPTION OF THE DRAWINGS

The above and other objects and features of the present invention will become better understood with respect to the following description of the preferred embodiments given in conjunction with the accompanying drawings, in which:

FIGS. 1A to 1B are cross-sectional views briefly illustrating a method for forming a metal contact based on tungsten through employing a conventional chemical vapor deposition method;

FIGS. 2A to 2D are cross-sectional views illustrating a method for forming a diffusion barrier layer made of titanium nitride (TiN) in accordance with the present invention;

FIGS. 3A to 3D are cross-sectional views illustrating a method for fabricating a contact formed on an interconnection line in accordance with the present invention;

FIGS. 4A to 4E are cross-sectional views illustrating a method for fabricating a contact formed on silicon in accordance with the present invention; and

FIGS. 5A to 5E are cross-sectional views illustrating a method for fabricating a contact formed on silicon in accordance with the present invention.

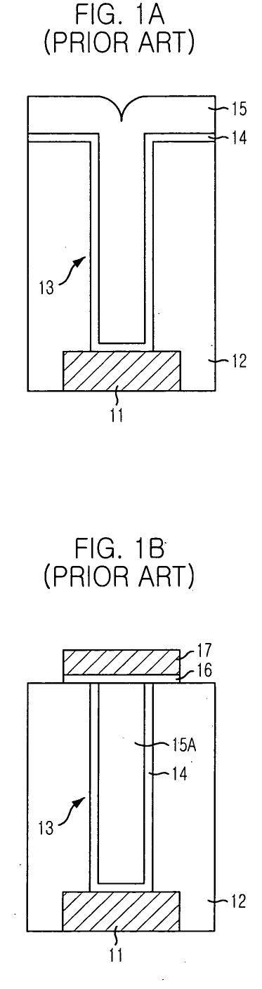

### DETAILED DESCRIPTION OF THE INVENTION

Hereinafter, detailed descriptions on preferred embodiments of the present invention will be provided with reference to the accompanying drawings.

Preferred embodiments of the present invention propose a method for fabricating a thin titanium nitride (TiN) diffusion barrier layer capable of securing a diffusion barrier capability as having excellent adhesion with lower layers by introducing a soaking technology with use of boron (B).

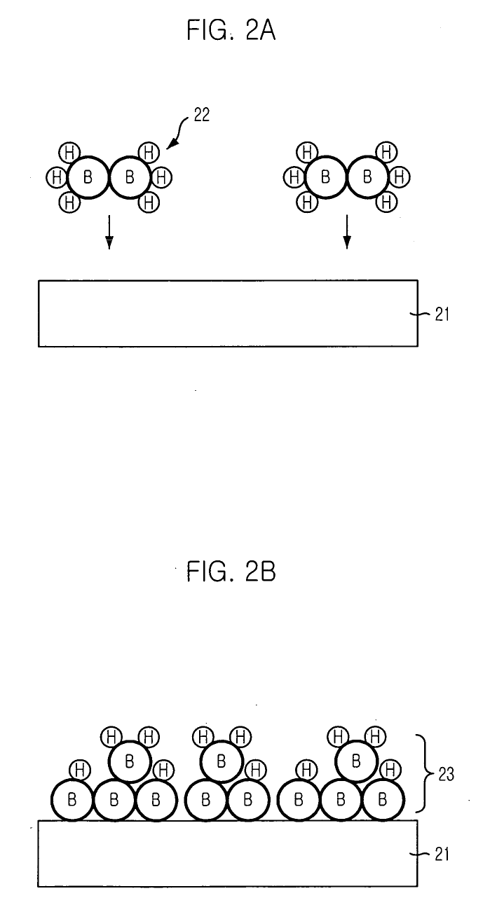

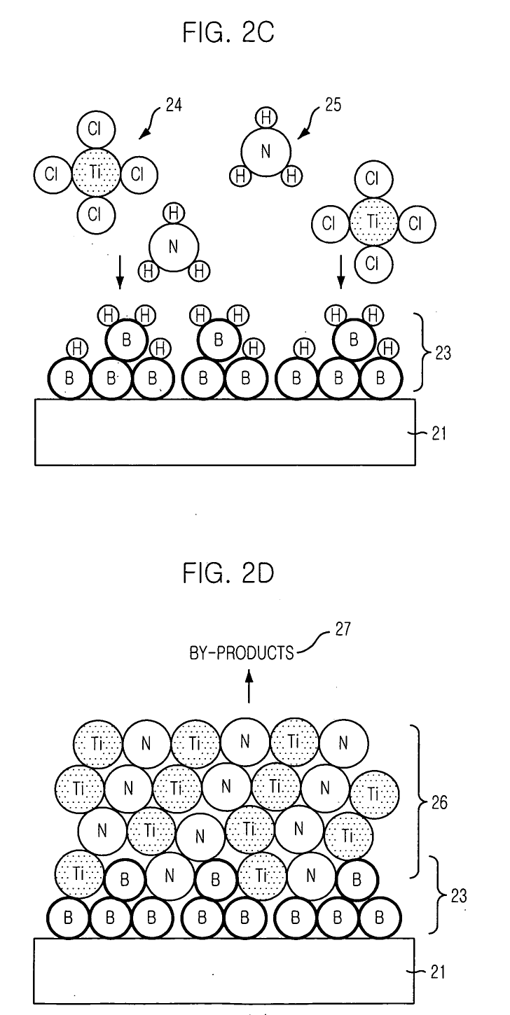

FIGS. 2A to 2D are cross-sectional views illustrating a method for forming a diffusion barrier layer made of titanium nitride (TiN) in accordance with the present invention.

Referring to FIG. 2A, as for a chemical vapor deposition (CVD) method for forming a TiN layer through a molecular reaction between titanium tetrachloride (TiCl₄) and ammonia (NH₃), diborane (B₂H₆) 22 as a soaking material is precedently introduced into a substrate 21 heated at a temperature ranging from approximately 100° C. to approximately 800° C. to induce a reaction. At this time, a pressure of a chamber is maintained in a range from approximately 0.1 mtorr to approximately 100 torr.

Referring to FIG. 2B, when the B₂H₆ 22 is introduced into the chamber, a number of soaking layers 23 are formed on a surface of the substrate 21. Herein, the soaking material serves a role in increasing the adhesion and helps the diffusion barrier layer to be grown in a layer-by-layer type by pre-treating the substrate 21 before depositing the diffusion barrier layer. A layer formed on the surface of the substrate after a surface pre-treatment process is called a soaking layer.

Referring to FIG. 2C, after forming the soaking layers 23, e.g., the boron layers, gases including TiCl₄ 24 and NH₃ 25 are introduced into the substrate 21.

Referring to FIG. 2D, if injecting the gases including TiCl₄ 24 and NH₃ 25, TiN nuclei are uniformly generated on the surface of the substrate 21 in a rapid speed because the borons adsorbed on the surface of the substrate 21 are rapidly reacted with TiCl₄ 24. Thus, a thin TiN layer 26 is continuously formed with a size ranging from approximately 1 nm to approximately 10 nm. At this time, reactive byproducts of chlorine (Cl) and hydrogen (H) are evaporated. Herein, a reference numeral 27 denotes these byproducts.

According to FIGS. 2A to 2D, the adhesion of the TiN layer 26 with the lower layers, i.e., the soaking layers 23, is greatly improved due to an uniform generation of the TiN nuclei and an wetting property of B.

Although the B₂H₆ 22 is exemplified as a main component to form the soaking layers 23 in FIGS. 2A to 2D, silane (SiH₄) can also be used as a main component to form the soaking layers. It is also possible to form the soaking layers 23 by performing a pre-treatment process with use of a plasma. The pre-treatment process is implemented by directly forming a plasma within a reactor including the soaking material with supplying a radio frequency (RF) or a direct current (DC) power above a substrate heated at a temperature ranging from approximately 0° C. to approximately 800° C. Also, the pre-treatment process is implemented by activating the soaking material with use of a remote plasma made of an inert gas such as argon (Ar); and pre-treating the surface of a substrate by using the activated soaking material.

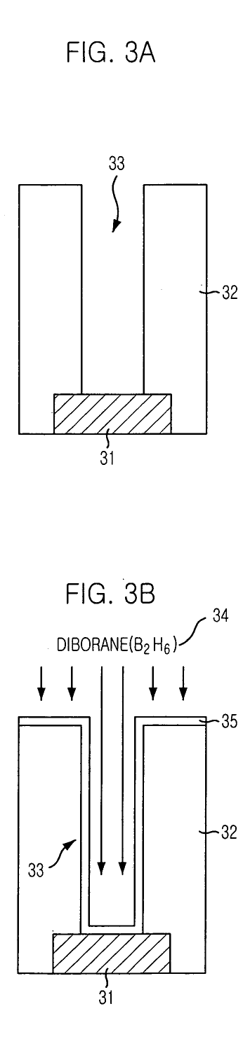

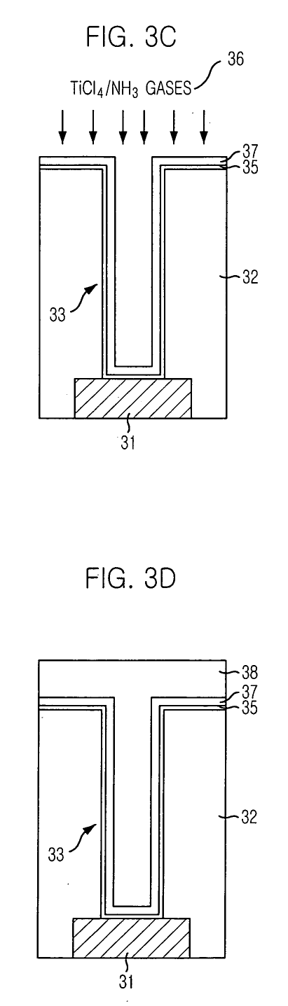

FIGS. 3A to 3D are cross-sectional views illustrating a a method for forming an opening formed on the interconnection line in accordance with a first embodiment of the present invention, wherein a method for forming a diffusion barrier layer shown in FIGS. 2A to 2D is applied to the opening formation method.

Referring to FIG. 3A, an inter-layer insulation layer or an inter-metal insulation layer 32 is formed on a lower metal interconnection line 31. Although the inter-metal insulation layer 32 is used for an explanation in the first embodiment, the present invention can apply to an inter-layer insulation layer. Afterwards, the inter-metal insulation layer 32 is etched to form an opening 33 exposing a portion of the lower metal interconnection line 31. The lower metal interconnection line 31 can be formed by using a material selected from a group consisting of tungsten (W), aluminum (Al), copper (Cu), titanium (Ti), titanium nitride (TiN), tantalum nitride (TaN), tantalum (Ta) and tungsten nitride (WN), and an upper metal interconnection line which will be formed later can be formed by using one of Al and Cu besides the W layer.

Referring to FIG. 3B, as B₂H₆ 34 serving as a soaking material is introduced into a CVD chamber maintained at a temperature ranging from approximately 400° C. to approximately 700° C., a glue layer 35 for absorbing the injected B₂H₆ 34 is formed in the contact hole 33 and on the inter-metal insulation layer 32. Herein, the glue layer 35 is formed by adsorbing borons from the B₂H₆ 34 until it grows from a sub-monolayer to several monolayers.

Referring to FIG. 3C, as predetermined gases 36 including TiCl₄ 24 and NH₃ 36 are introduced into the CVD chamber, TiN nuclei are uniformly generated on the glue layer 35 in a rapid speed because the glue layer 35 is rapidly reacted with the TiCl₄ of the predetermined gases 36. Thus, a thin TiN layer 37 is continuously formed with a size ranging from approximately 1 nm to approximately 10 nm. At this time, reactive byproducts of chlorine (Cl) and hydrogen (H) are evaporated.

Referring to FIG. 3D, a tungsten layer 38 is deposited on the thin TiN layer 37 through a CVD method until being filled into the contact hole 33. Herein, when depositing the tungsten layer 38 through the CVD method, tungsten hexafluoride (WF₆) is used as a source gas.

In accordance with the above embodiment, a process for introducing the soaking material can be performed in a separate chamber from the CVD chamber for forming the TiN layer. However, if the injection process of the soaking material is performed in-situ at the identical chamber to the CVD chamber, an improvement on a throughput and cost-effectiveness can be achieved.

In accordance with the above embodiment, the thin TiN layer 37 is formed on the glue layer 35 as a diffusion barrier layer. The thin TiN layer 37 is thin and uniform and, has excellent adhesion since the thin TiN layer 37 is formed on the glue layer 35.

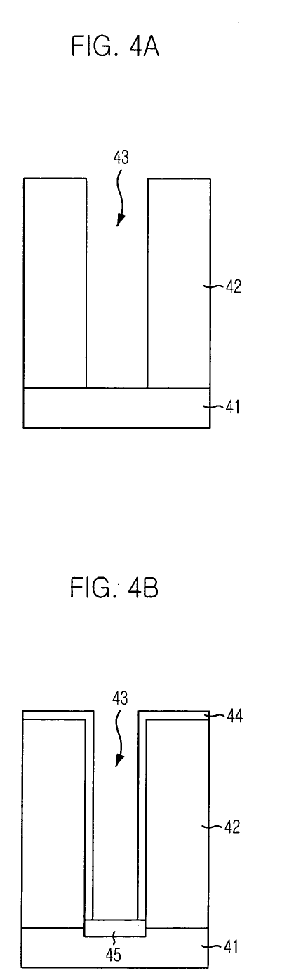

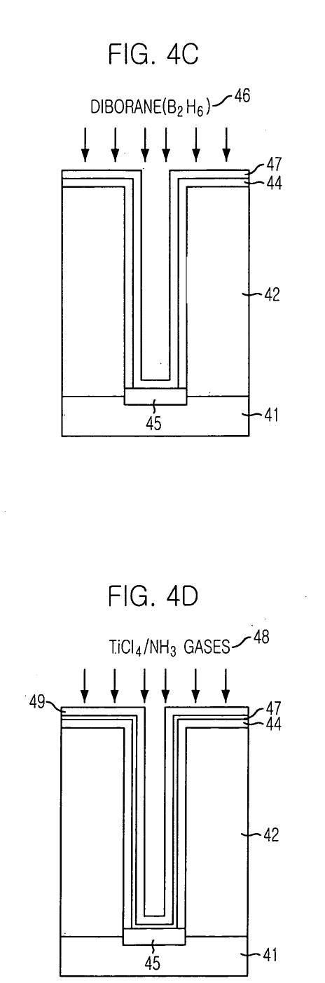

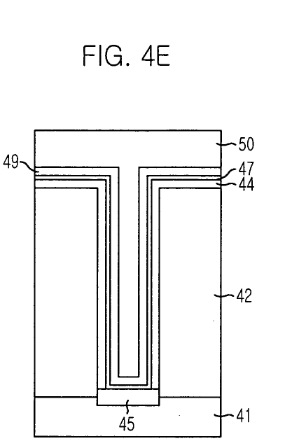

FIGS. 4A to 4E are cross-sectional views illustrating a method for forming an opening on a silicon substrate in accordance with a second embodiment of the present invention, wherein a method for forming a diffusion barrier layer shown in FIGS. 2A to 2D is applied to the opening formation method.

Referring to FIG. 4A, an inter-layer insulation layer 42 is formed on a semiconductor layer 41 containing silicon. Afterwards, the inter-layer insulation layer 42 is etched, thereby forming an opening 43 exposing a portion of the semiconductor layer 41.

Referring to FIG. 4B, a chemical vapor deposition (CVD) method is employed to form a Ti layer 44. For the CVD method, TiCl₄ and H₂ gases are used. At this time, the Ti layer 44 is deposited on a portion of the semiconductor layer 41 exposed by the contact hole 43, inner walls of the contact hole 43 and the inter-layer insulation layer 42.

Meanwhile, since the deposition of the Ti layer is performed at a high temperature ranging from approximately 400° C. to approximately 700° C., silicon from the semiconductor layer 41 and Ti from the Ti layer 44 react with each other during depositing the Ti layer 44, thereby forming a titanium silicide (TiSi₂) layer 45 on the portion of the semiconductor layer 41 exposed by the opening.

As mentioned above, it is possible to form the TiSi₂ layer 45 as simultaneously as to deposit the Ti layer 44 because an additional thermal process Is not required owing to the fact that the CVD method for forming the Ti layer 44 is performed in a high temperature.

Referring to FIG. 4C, the semiconductor layer 44 on which the Ti layer 44 is deposited is transferred to the CVD chamber maintained at a temperature ranging from approximately 400° C. to approximately 700° C. Afterwards, B₂H₆ 46 is introduced into the CVD chamber as a soaking material and then, a B₂H₆ based glue layer 47 is formed on the Ti layer 44. Herein, the B₂H₆ based glue layer 47 is formed with B originated from the B₂H₆ 46 and grows from a sub-monolayer to several monolayers.

Referring to FIG. 4D, as predetermined gases 48 including TiCl₄ and NH₃ are injected, TiN nuclei are uniformly generated on the B₂H₆ based glue layer 47 in a rapid speed because the B₂H₆ based glue layer 47 is rapidly reacted with the TiCl₄ of the predetermined gases 48. Thus, a thin TiN layer 49 is continuously formed with a size ranging from approximately 1 nm to approximately 10 nm. At this time, reactive byproducts of Cl and H₂ are evaporated.

Referring to FIG. 4E, a tungsten layer 50 is deposited on the thin TiN layer 49 until being filled into the contact hole 43. At this time, during depositing the tungsten layer 50 through a CVD method, WF₆ is used as a source gas.

As explained in FIGS. 4A to 4E, in case of forming the opening on the semiconductor layer containing silicon, the TiSi₂ layer is formed at a bottom portion of the opening for the purpose of reducing a contact resistance and then, the thin TiN layer acting as a diffusion barrier layer is formed. Herein, the B₂H₆ based glue layer provides an advantage of preventing Cl included in the TiCl₄ gas from inducing damage to the TiSi₂ layer during depositing the thin TiN layer 49 with use of the TiCl₄ and NH₃ gases.

In addition to the titanium silicide (Si₂) layer, one of tantalum silicide (TaSi₂), tungsten silicide (WSi₂), cobalt silicide (CoSi₂), and nickel silicide (NiSi₂) can be employed as the silicide material formed on the predetermined portion of the opening. Thus, it is further possible to use one of tantalum (Ta), tungsten (W), cobalt (Co), and nickel (Ni) in addition to the Ti layer formation.

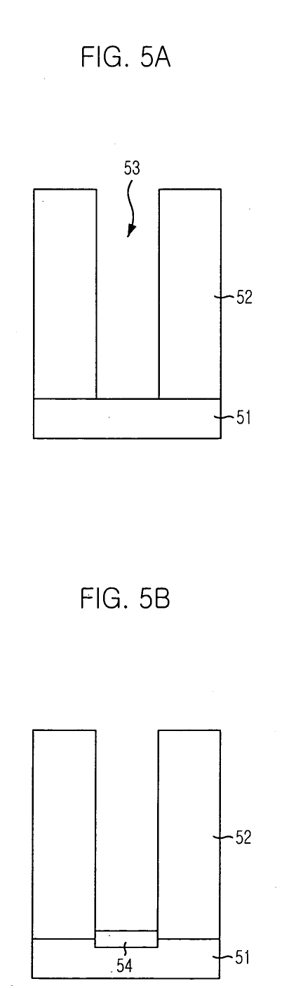

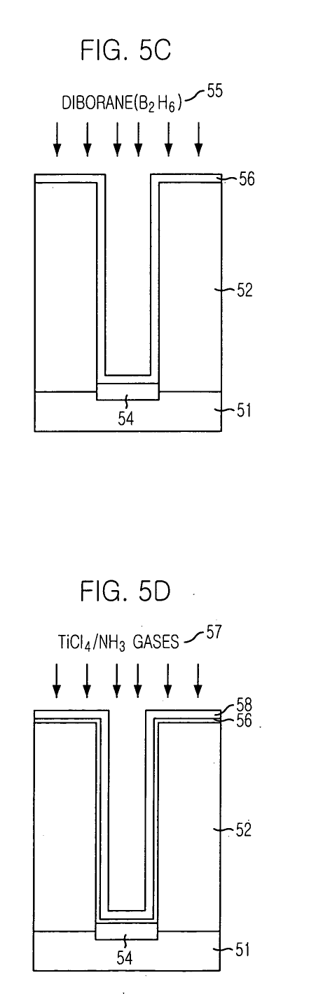

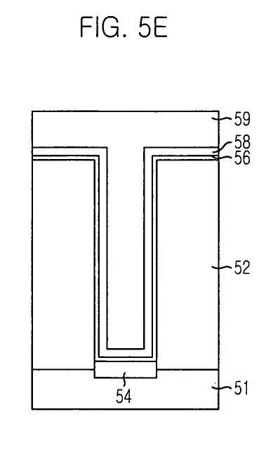

FIGS. 5A to 5E are cross-sectional views illustrating a method for forming an opening formed on silicon, wherein a method for forming a diffusion barrier layer shown in FIGS. 2A to 2D is applied to the opening formation method.

Referring to FIG. 5A, an inter-layer insulation layer 52 is formed on a semiconductor layer 51 containing silicon and then, an opening 53 exposing a portion of the semiconductor layer 51 is formed by etching the inter-layer insulation layer 52.

Referring to FIG. 5B, a TiSi₂ layer 54 is formed directly on a portion of the semiconductor layer 51 exposed by the opening 53 by performing a salicide process.

Herein, the salicide process proceeds by employing several sequential steps. Although not illustrated, a Ti layer is first formed by performing a physical vapor deposition (PVD) method. Then, a predetermined thermal process is adopted to induce a reaction between the semiconductor layer 51 including silicon and the Ti layer, thereby forming the TiSi₂ layer 54 on the portion of the semiconductor layer 51 exposed by the opening 53. Afterwards, non-reacted titanium molecules are removed.

Referring to FIG. 5C, the semiconductor layer 51 with the TiSi₂ layer 54 is loaded to a CVD chamber maintained at a temperature ranging from approximately 400° C. to approximately 700° C. Afterwards, as B₂H₆ 55 serving as a soaking material is injected into the CVD chamber, a B₂H₆ based glue layer 56 is formed on the inter-layer insulation layer 52, and the TiSi₂ layer 54. Herein, the B₂H₆ based glue layer 56 is formed as borons contained in the soaking material, i.e., the B₂H₆ 55 are adsorbed on the B₂H₆ based glue layer 56 and grows from a sub-monolayer to several monolayers.

Referring to FIG. 5D, as predetermined gases 57 including TiCl₄ and NH₃ are introduced into the CVD chamber, TiN nuclei are uniformly generated in a rapid speed because the B₂H₆ based glue layer 56 is rapidly reacted with the TiCl₄ gas of the predetermined gases 57. Thus, a thin TiN layer 58 is continuously formed with a size ranging from approximately 1 nm to approximately 10 nm. At this time, reactive byproducts of Cl and H₂ are evaporated.

Referring to FIG. 5E, a tungsten layer 59 is deposited on the thin TiN layer 58 until being filled into the contact hole 53. At this time, during depositing the tungsten layer 59 through the CVD method, WF₆ is used as a source gas.

As described through FIG. 5A to FIG. 5E, in case of forming the opening on the semiconductor layer containing silicon, the TiSi₂ layer is formed at a bottom portion of the opening for reducing the contact resistance and then, the thin TiN layer acting as a diffusion barrier layer is formed. Herein, the B₂H₆ based glue layer provides an advantage of preventing Cl included in the TiCl₄ gas from inducing damage to the TiSi₂ layer during depositing the thin TiN layer with use of TiCl₄ and NH₃.

In addition to the TiSi₂ layer, it is possible to employ one of TaSi₂, WSi₂, CoSi₂, and NiSi₂.

In addition, tantalum nitride (TaN), tungsten nitride (WN), titanium tungsten (TiW) and an amorphous metal that are used as the diffusion barrier layer can be uniformly formed in a thin thickness while being capable of functioning the diffusion barrier layer as simultaneously as having excellent adhesion obtained by introducing the soaking technology.

The present invention provides effects of reducing a metal contact resistance of a highly integrated semiconductor device and improving adhesion of the TiN layer used as the diffusion barrier layer against the tungsten layer with lower layers disposed beneath the TiN layer.

Furthermore, since the thin TiN layer is highly densified, a property of the diffusion barrier layer is enhanced and, since the diffusion barrier layer is formed through the CVD method under the presence of the glue layer containing the soaking material, the lower layers can be protected from contaminations, e.g., halogen elements, which can be generated from precursors used in the CVD method.

The present application contains subject matter related to the Korean patent application No. KR 2004-0031921, filed in the Korean Patent Office on May 6, 2004, the entire contents of which being incorporated herein by reference.

While the present invention has been described with respect to certain preferred embodiments, it will be apparent to those skilled in the art that various changes and modifications may be made without departing from the spirit and scope of the invention as defined in the following claims.

1. A method for fabricating a semiconductor device, comprising the steps of:
forming an insulation layer a metal interconnection line;
etching the insulation layer, thereby forming an opening to expose a portion of the metal interconnection line;
forming a soaking layer on the insulation layer and the opening;
forming a diffusion barrier layer on the soaking layer; and
filling a metal layer into the opening.

2. The method of claim 1, wherein the soaking layer is formed by using diborane (B₂H₆).

3. The method of claim 1, wherein the soaking layer is formed by using silane (SiH₄).

4. The method of claim 1, wherein the soaking layer is formed through a chemical vapor deposition method.

5. The method of claim 1, wherein the soaking layer is formed through a plasma atmosphere.

6. The method of claim 1, wherein the soaking layer is formed at a temperature ranging from approximately 100° C. to approximately 800° C. and under a pressure ranging from approximately 0.1 mtorr to approximately 100 torr.

7. The method of claim 1, wherein the soaking layer is formed by directly forming a plasma at a temperature ranging from approximately 0° C. to approximately 800° C. by using one of a radio frequency power and a direct current power.

8. The method of claim 1, wherein the step of forming the soaking layer, comprising the steps of:
activating a soaking material by using a remote plasma including an inert gas; and
providing a pre-treatment process by using the activated soaking material.

9. The method of claim 1, wherein the diffusion barrier layer is formed by using a material selected from a group consisting of titanium nitride (TiN), tantalum nitride (TaN), tungsten nitride (WN), titanium tungsten (TiW) and an amorphous metal.

10. A method for fabricating a semiconductor device, comprising the steps of:
forming an insulation layer on a semiconductor layer containing silicon;
etching the insulation layer, thereby forming an opening to expose a portion of the semiconductor layer;
forming a silicide layer on the exposed portion of the semiconductor layer;
forming a soaking layer on the silicide layer and the opening;
forming a diffusion barrier layer on the soaking layer; and
filling the opening with a metal layer.

11. The method of claim 10, wherein the soaking layer is formed by diborane (B₂H₆).

12. The method of claim 10, wherein the soaking layer is formed by silane (SiH₄).

13. The method of claim 10, wherein the soaking layer is formed through a chemical vapor deposition method.

14. The method of claim 10, wherein the soaking layer is formed through a plasma atmosphere.

15. The method of claim 10, wherein the soaking layer is formed at a temperature ranging from approximately 100° C. to approximately 800° C. and under a pressure ranging from approximately 0.1 mtorr to approximately 100 torr.

16. The method of claim 10, wherein the soaking layer is formed by directly forming a plasma at a temperature ranging from approximately 0° C. to approximately 800° C. by using one of a radio frequency power and a direct current power.

17. The method of claim 10, wherein the step of forming the soaking layer, comprising the steps of:
activating a soaking material by using a remote plasma including an inert gas; and
providing a pre-treatment process by using the activated soaking material.

18. The method of claim 10, wherein the diffusion barrier layer is formed by using a material selected from a group consisting of titanium nitride (TiN), tantalum nitride (TaN), tungsten nitride (WN), titanium tungsten (TiW) and an amorphous metal.

19. The method of claim 10, wherein the step of forming the silicide layer includes the step of forming a metal layer on the opening and the insulation layer by employing a chemical vapor deposition method at a high temperature, thereby forming the silicide layer on a portion of the semiconductor layer exposed by the opening during the formation of the metal layer.

20. The method of claim 10, wherein the metal layer is based on a material selected from a group consisting of Ti, Ta, W, Co and Ni.

21. The method of claim 10, wherein the step of forming silicide layer includes the steps of forming a metal layer on the opening and the insulation layer by employing a chemical vapor deposition method at a high temperature, thereby forming the silicide layer on a portion of the semiconductor layer exposed by the opening during the formation of the metal layer.

22. The method of claim 21, wherein the metal layer is based on a material selected from a group consisting of Ti, Ta, W, Co and Ni.
